(19) United States
(12) Patent Application Publication
(10) Pub. No.: US 2009/0312968 A1
(43) Pub. Date: Dec. 17, 2009

(54) POWER CONSUMPTION FEEDBACK SYSTEMS

(75) Inventor: Amyas Edward Wykes Phillips, Cambridge (GB)

Correspondence Address: LOGINOV & ASSOCIATES, PLLC, 10 WATER STREET, CONCORD, NH, 03301, US

(73) Assignee: ALERTME.COM.LTD, Cambridge (GB)

(21) Appl. No.: 12/482,019

(22) Filed: Jun. 10, 2009

Related U.S. Application Data
(60) Provisional application No. 61/075,056, filed on Jun. 24, 2008.

(30) Foreign Application Priority Data
Jun. 13, 2008 (GB) GB0810862.3

(51) Int. Cl. G01R 21/00; G06F 19/00

(52) U.S. Cl. 702/62

(57) ABSTRACT

An electrical power supply consumption feedback system including a current transducer configured to be attached externally to a mains power supply cable providing a mains power supply to said building to measure a current of said mains power supply, a voltage measurement system configured to measure within said building a voltage of said mains power supply, a system controller coupled to said voltage measurement system and to said current transducer and having a system controller wireless interface, at least one of said current transducer and said voltage measurement system having a complementary wireless interface and being coupled to said system controller via the wireless interface, and wherein said system controller is configured to calculate a power consumption of said building from said measured current and voltage; and a display coupled to said system controller to display a visual indication of said calculated power consumption.

### RELATED APPLICATIONS

This application claims the benefit of U.S. Provisional Application Ser. No. 61/075,056, filed Jun. 24, 2008, entitled POWER CONSUMPTION FEEDBACK SYSTEMS, the entire disclosure of which is herein incorporated by reference. This application claims foreign priority benefits of United Kingdom Application Ser. No. GB0810862.3, filed Jun. 13, 2008, entitled POWER CONSUMPTION FEEDBACK SYSTEMS, the entire disclosure of which is herein incorporated by reference.

### FIELD OF THE INVENTION

This invention relates to apparatus, methods and computer program code for obtaining an accurate measurement of a premises' electrical energy consumption using an inductively-coupled electric current meter at the mains connection and one of several means of inferring the voltage remotely. Other aspects relate to encouraging energy efficiency by automatically providing feedback to users showing their energy consumption relative to that of other people.

### BACKGROUND OF THE INVENTION

Electricity meters are installed at practically all sites where electrical energy is consumed. They are designed to be as cheap and reliable as possible, while performing their primary function of measuring and recording the cumulative total of electrical energy consumed. These measurements are made on behalf of the electricity suppliers, who typically bill customers according to the amount of electrical energy consumed.

Although these meters use a variety of electronic and electromechanical measurement mechanisms, certain other features are common to all. All meters are calibrated at manufacture. All meters are installed in series on the electrical mains supply line at the point of connection to a premises' distribution network, so that all electricity consumed on the premises must pass through the meter. If a premises is connected to more than one phase of the electricity supply, each phase will be connected through its own meter. Because meters and their associated wiring are unsightly, they are usually sited in out-of-the-way and consequently hard to access locations. Numeric human-readable output is always present, usually in the form of dials, decade counters or liquid crystal digital (LCD) displays. These counters tend to advance only slowly in everyday use, so to help installers and meter readers verify correct operation a low flow indicator in the form of a Ferraris disc with a black sector or a pulsing light-emitting diode (LED) is often also included. The fiduciary significance of meter readings means that installation can only be performed by trusted personnel, and anti-tamper features are universal.

Electricity suppliers typically employ corps of specialist staff to read customers' meters, at considerable expense. To minimize this, domestic meters have traditionally only been read at intervals of between six and twenty-four months, commercial premises at intervals of one to three months. Billing is usually conducted monthly, and has therefore often been based on estimated readings. Estimated readings can diverge significantly from real readings in the interval between meter readings, so customers are often invited to read and report their meter readings themselves—not always a straightforward task.

Traditional meters are well adapted to their function of providing reliable, infrequent readings to the electricity supplier. In recent years technology has begun to make possible meters which can be read remotely, without staff physically visiting customers' premises. Automated Meter Reading (AMR) has the potential to greatly reduce the ongoing cost to suppliers of reading meters, but the capital outlay involved in deploying such technology has so far prevented its widespread use.

AMR has benefits for consumers also. By dispensing with estimated readings, it makes it much easier for customers to see how changes in their energy consumption behaviour affect their monthly energy bill. This feedback is crucial in helping electricity users evaluate the efficacy of energy-saving measures. AMR thus provides environmental benefits as well as cost savings for both electricity suppliers and users.

Research has shown that although monthly feedback results in small reductions in energy use, much greater saving are available when feedback is given even more frequently. Taking this idea to its logical conclusion, giving feedback every few seconds, allows customers to see and respond to their electricity usage immediately. It also becomes easy to determine the energy usage of particular appliances. Being clearly beneficial to both the customer and the environment, rapid feedback is widely desired. However, there is a problem in that its provision imposes extra costs on the supplier, who must provide some kind of display device to each customer, preferably separate and more accessible than the meter itself, in order to deliver energy usage feedback.

An adaptation of AMR technology known as Advanced Metering Infrastructure (AMI) solves this by allowing suppliers to split the gains with their customers. AMI makes the AMR infrastructure two-way, allowing suppliers to use the feedback device to advise customers of electricity prices as well as of their usage. In this way suppliers gain the flexibility to set time-dependant tariffs which discourage use at times of peak demand. Reducing peak demand and smoothing usage over the day allows suppliers to save money on distribution infrastructure and generate electricity more efficiently.

Deploying AMI remains a significant capital and engineering project, a work of decades. In order to realise some cost and environmental benefits immediately, many electricity users are willing to buy and fit their own monitoring and feedback equipment. At a minimum, this needs to include some means for monitoring electricity usage and some means for feeding this back to the user. Exact measurement of AC electricity usage requires actual or implicit knowledge of voltage, current, their waveforms and relative phases. Only equipment placed in electrical series in the mains supply at the point to connection to the premises can access all these parameters directly. Interfering with the meter installation itself is generally prohibited, but users may consider having a second, ‘smart’ meter of their own installed between their fiduciary meter and their distribution board. This is necessarily a costly operation.

For the purposes of providing rapid feedback to electricity users, exact usage measurements are not essential and it is frequently sufficient to have approximate readings. These can be obtained cheaply and easily by means of a ‘clip-on’ device placed around one of the mains cables entering the fiduciary meter. Such devices are typically part of a user-installable system which measures current using a simple inductive coil, calculates power consumption and feeds back some representation of it to the user via a display of some kind. Cheap and easy to set up, these systems often rely heavily on various assumptions.

AC current passing through the mains cable induces a voltage in the coil which is is related to the current in the mains cable by a multiplicative constant, and which can be measured by an AC voltmeter. This reading can be readily converted to a power measurement, with the aid of two further pieces of information: voltage, and power factor.

AC current varies in phase with voltage, when driving resistive loads. Reactive loads however store energy during part of each cycle and release it during the other part, having the effect of shifting voltage phase relative to current phase. In either case, the power being transferred at any instant is simply the product of voltage and current. As voltage and current move out of phase, their average product over each cycle falls, becoming zero when they are 90 degrees out of phase. Power factor is calculated as ratio of power actually transferred to the power that would be transferred if voltage and current were in phase, so it is unity when voltage and current are in phase, and zero when they are 90 degrees out of phase. Power factor is not measurable using an inductive coil, with which one can only measure the current. In practice, for most domestic usage it is reasonable to assume unity power factor, although for some loads such as vacuum cleaner motors this assumption may result in some slight over-reporting of power consumption.

Of more importance is the supply voltage, which varies significantly between locations. Near an electricity substation, voltage may be high—up to 253.0V in the UK. Far from the local substation, after resistive losses in the distribution network, the supply voltage can fall significantly—as low as 216.2V in the UK. Most electrical equipment will operate satisfactorily throughout this range, but because it represents a variation up to +10% above and −6% below the expected 230V any ‘clip-on’ power monitoring device based on an inductive coil and assuming a 230V supply may report power consumption up to 10% in error.

Supply voltage can also vary during the day, falling slightly during high-load periods, but this variation is small compared with the location dependence.

As discussed above, exact readings are not crucial to effective energy-use feedback, but errors of 10% do begin to undermine their usefulness. In particular, it becomes difficult to compare data across locations, which is important if the objective is to tell users how they rank against similar users. Users also trust the feedback less, making it less effective. With sufficiently accurate readings, clip-on devices may even be useful to electricity suppliers as interim AMR devices. It is desirable, therefore, for clip-on devices to be accurate to within a few per cent. In the UK, fiduciary meters are themselves required to be accurate only to within +2.5% and −3.5% of actual energy consumption. This is generally achievable with clip-on meters simply by having the device factor in the local supply voltage, instead of assuming a nominal value.

Background prior art can be found in “The Effectiveness of Feedback on Energy Consumption-A Review for DEFRA of the Literature on Metering, Billing and Direct Displays” by Sarah Darby of the University of Oxford's Environmental Change Institute (http://www.eci.ox.ac.uk/research/energy/electric-metering.php), and in, for example, WO02/084309.

### SUMMARY OF THE INVENTION

There is provided a combination of clip-on power monitors with automatic and user-friendly procedures and mechanisms for determining the local mains electrical supply voltage, in order to enhance accuracy and energy efficiency. In embodiments the monitor and/or display unit determines the voltage automatically from remote elements of the same system which are connected directly to the mains themselves or else obtain readings from the fiduciary meter for calibration purposes.

The monitors are provided in a power consumption feedback system for recording and reporting to users the use of electrical energy. The system includes at least one ‘clip-on’ inductive loop-based current measuring device for monitoring current drawn though one or more connections to the mains electrical distribution system, at least one means of displaying the information to users, at least one means of obtaining line voltage or fiduciary meter readings, and at least one system controller coupled to the other elements.

In some preferred implementations the system is part of an intruder alarm. In such an implementation functions of the intruder alarm system already present, such as display devices, logging to remote servers and remote web access are also employed as part of the energy monitoring system.

Thus according to an aspect of the invention there is therefore provided an electrical power supply consumption feedback system for providing feedback on power consumption in a building, the system comprising: a current transducer configured to be attached externally to a mains power supply cable providing a mains power supply to said building to measure a current of said mains power supply; a voltage measurement system configured to measure within said building a voltage of said mains power supply; a system controller coupled to said voltage measurement system and to said current transducer and having a system controller wireless interface, at least one of said current transducer and said voltage measurement system having a complementary wireless interface and being coupled to said system controller via said system controller wireless interface, and wherein said system controller is configured to calculate a power consumption of said building from said measured current and voltage; and a display coupled to said system controller to display a visual indication of said calculated power consumption.

Embodiments of the above-described system enable a more accurate determination of power consumption to be made, which is particularly important when comparing, for example, power consumption between households. In embodiments the current and voltage measurements are true or assumed RMS measurements. Some preferred embodiments of the system are distributed with wireless, for example Zigbee (RTM) links between the different components of the system.

One significant factor influencing the mains voltage at a building is its distance from the local substation. Since this does not change, in some embodiments of the system only a single voltage measurement need be made in order to calibrate the system. However since voltage can also vary to some degree with time of day (that is, load) in other embodiments substantially continuous measurement of the mains voltage may be employed.

We have previously described, in GB 0804275.6 filed 7 Mar. 2008 a system, preferably part of an intruder alarm system, in which a plug-through device is used to monitor a power state of an electrical appliance and an occupancy detection device is used to detect human presence in a location of the electrical appliance, automatically switching off the appliance in the absence of human presence.

In some preferred embodiments of the system such a plug-through controller may be employed to measure the mains voltage. This is advantageous in part because such a device will generally already include a voltage sensor as well as a wireless communications link for connecting to a system controller. In embodiments either the system controller or the plug-through controller may be configured only to measure the mains voltage when any appliance connected to the plug-through controller is switched off (the plug-through controller may only measure at such times and/or the system controller may only use measurements made at such times). Whether the appliance is on or off can be determined by means of a current measuring device in the plug-through controller which, again, may be present for other reasons. By measuring when the appliance is off small voltage drops due to resistive losses in the local mains power distribution network may be avoided.

In other embodiments the voltage measurement system may comprise a user interface for the system controller to enable a user to input two readings of the electricity meter for the premises spaced apart by a time interval. This enables a one-off calibration of the system by adjusting and assumed voltage used by the system until the measured power consumption matches that over the same period deduced from the two meter readings. The user interface may be implemented, for example, as a website, optionally via a remote server where the system controller has a connection to the server over the internet With such an arrangement preferably the time interval is relatively long, for example a day, a week, or a fortnight as in this way it becomes less important for the user to precisely time when the electricity meter readings are made.

In still other embodiments the voltage measurement system may comprise a system to remotely read the electricity meter of the building. For example an optical system may be employed to monitor rotation of a mechanical disk and/or flashing of a light emitting diode (in some meters these flash every Watt-hour used).

It might be thought that if the electricity utility meter was being monitored directly this would obviate the need for a voltage measurement system and current transducer, but in fact such an arrangement allows substantially instantaneous variations in the power consumption to be displayed whereas a utility meter might only provide readings every ten or twenty seconds. The information provided by the utility meter relates to energy consumption and can therefore be employed to calibrate the system by determining an assumed voltage, as described above.

In some preferred implementations power consumption data from the system is uploaded to a central server and provided to a website to enable a user to compare their own power consumption with that of others, preferably those who are expected to have similar power consumption. The increased accuracy of power consumption determination provided by a system as described above is particularly helpful when making such comparisons between users.

In a related aspect, therefore, the invention provides an electrical power supply consumption feedback system for providing feedback on power consumption in a building, the system comprising: a plurality of in-building electrical power supply consumption monitoring systems, each having an interface for coupling the respective system to a network; a system controller having an interface to said network for connecting to each of said monitoring systems to receive power consumption data from said monitoring systems; and a plurality of user feedback terminals each for providing feedback on to a respective user of a monitored building and each couplable to said system controller to provide said feedback on in-building monitored power consumption; and wherein said system controller is configured to provide to a user of said system, via a said user feedback terminal information on a relative power consumption of a monitored building of the user in comparison with one or more others of said monitored buildings.

In embodiments the system controller is implemented as a server connected to the internet although the skilled person will appreciate that other forms of communication, for example communication using a mobile phone network, may also be employed.

In some preferred embodiments the system controller provides an interface, for example a web interface, for a user, to capture energy efficiency data relating to an energy efficiency of their building. Such data may include, for example, the building's size, age, location, occupancy (number of people), in the UK a Home Information Pack star rating (which relates to the sustainability of the property) and the like. In this way the energy consumption of a building may be displayed alongside its peers and/or an adjustment or weighting may be applied depending upon the energy efficiency data.

In embodiments of the system the temperature at one or more locations in a building may be monitored and this may be employed to estimate the amount of heating which is supplied to the house. Optionally an estimate of a degree of hot water heating employed may also be made. In combination with the electrical power consumption this may then be employed to determine a value representing the carbon footprint or sustainability of a building and this value may be provided as feedback to a user additionally or alternatively to the in-building monitored power consumption. In more detail, for example, the thermal mass of the building may be estimated from cooling of the building when the heating is turned off (which can be seen from the temperature curve); an adjustment may be also made for an estimated or measured external temperature, for example from publicly available weather data. Optionally a hot water temperature sensor may be employed in a similar way to determine an estimate for water heating energy consumption.

In embodiments an occupancy detection system for the building and/or for one or more rooms of the building incorporated into the in-building electrical power supply consumption monitoring system may be employed to obtain more accurate data. Similarly one or more plug-through controllers as described above may be employed to obtain more accurate/finer granularity data including, for example data on specific high energy appliances. Optionally in embodiments the collected data may even be employed to provide a user with suggestions as to how energy consumption might be reduced.

As noted above, it is helpful for such a system to have accurate data and, therefore, it is preferable to employ an electrical power supply consumption feedback system according to an embodiment of the first aspect of the invention described above.

In other aspects the invention provides: the system controller described above for providing relative power consumption information to users; a method of implementing an electrical power supply consumption feedback system according to either of the aspects of the invention described above, and corresponding computer program code.

### BRIEF DESCRIPTION OF THE DRAWINGS

The invention description below refers to the accompanying drawings, of which:

FIG. 1 shows schematically components of a comparative energy feedback system according to an embodiment of the invention;

FIG. 2 is a flow chart of a set-up procedure for commissioning an accurate user-installable energy feedback system into use;

FIG. 3 illustrates in simplified form elements of an embodiment of the invention;

FIG. 4 shows a schematic implementation of an implementation of a plug-in mains voltage monitor as part of a plug-through controller;

FIG. 5 shows the functional elements of a clip-on current meter;

FIG. 6 shows the functional modules of an example embodiment of a combined home monitoring system controller;

FIG. 7 shows an exploded diagram of a plug-in device suitable for monitoring of mains voltage and also monitoring and control of attached appliance;

FIG. 8 shows an example embodiment of a domestic energy, occupancy and security monitoring system; and

FIG. 9 shows in schematic form an example of information flow in an energy monitoring and comparative feedback service.

### DETAILED DESCRIPTION

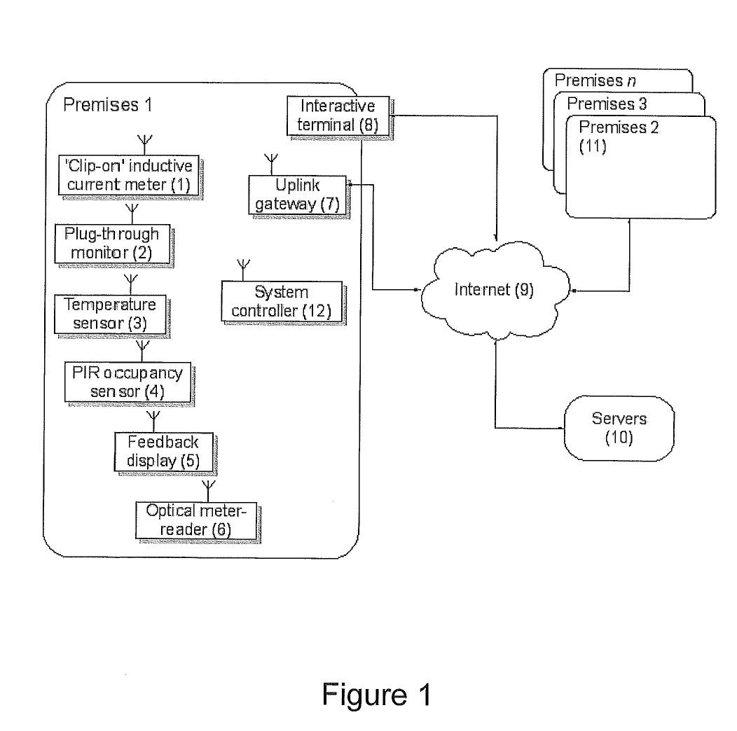

FIG. 1 shows schematically various components of a comparative energy feedback system. A customer's premises is outfitted with energy-related sensors including, of those shown, some subset. For accurate energy reporting the core elements are the “clip-on” inductive current meter (1), a system controller (12) and a feedback display (5).

The system controller (12) computer logic for calculating power usage from the current measurements may be separate, located remotely off site as part of a client-server application architecture, or co-located with the inductive current meter (1), the feedback display (5) or an uplink gateway (7). In any case at least two of these devices communicate using a local-area wireless communications protocol, using proprietary RF modulation schemes and protocols, or standards such as IEEE 802.15.4 (WiFi), Bluetooth®, or ZigBee®

Occupancy sensors (4) may be included in the system to allow the computer logic to change its behaviour according to whether anybody is present or not, e.g. by commanding a plug-through controller (2) to turn on or off power to an appliance.

A plug-through monitor such as (2) may also be used to measure and report mains supply voltage to the system controller (12), removing the need for a user to make manual meter readings. Another way to minimise demands on the user is to fit an optical meter reading device (6) of some description to the fiduciary meter and having it report the meter's readings to the system automatically.

The feedback display (5) may take any form suitable for the indication of energy consumption data to the customer, typically it will be a liquid crystal display or an ambient device such as a multicolour glowing lamp.

Adding in an uplink gateway and remote servers (10) allows the viewing of data using an interactive terminal (8) such as a web browser, with provision of comparative performance data from other people (11).

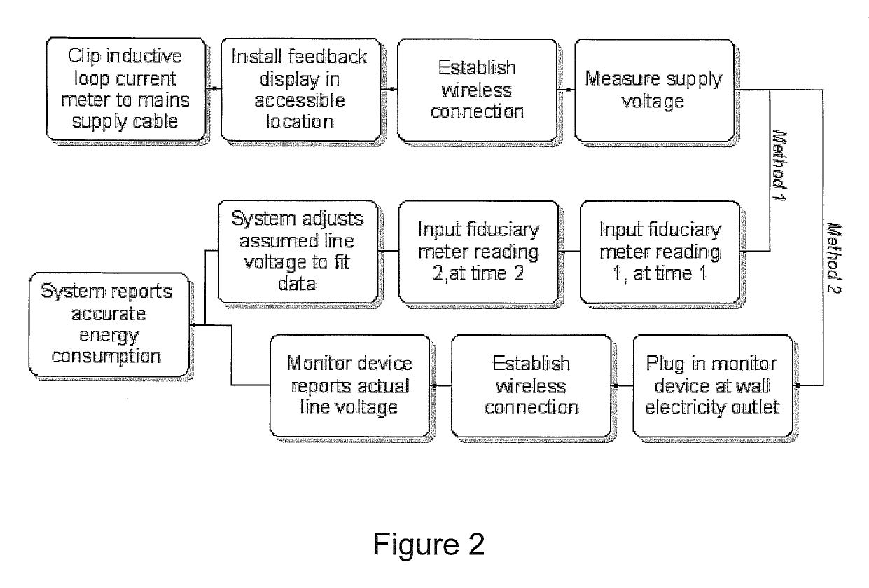

FIG. 2 is a flow chart of a set-up procedure for commissioning an accurate user-installable energy feedback system in to use. In this example, the system control computer logic is embedded in the inductive current meter or in the feedback display, and the two are placed in communication wirelessly. The next step after installing those items is to determine an accurate figure for the local mains supply voltage. Two methods are shown. Method one requires the user to manually read the fiduciary meter at two times separated by an interval of, ideally, a week. On entry of the second reading to the system, the control logic recalculates its estimate of energy usage over the same interval, adjusting V until its own energy consumption figure matches the fiduciary meter's. Method on might also be executed by means of an automated optical meter reader. Method two requires an independent measurement of the mains voltage using a voltmeter device plugged in to a wall electrical outlet. This is likely to also communicate wirelessly. In either case, once the system has obtained accurate figures for the local mains voltage, it will report accurately on energy usage.

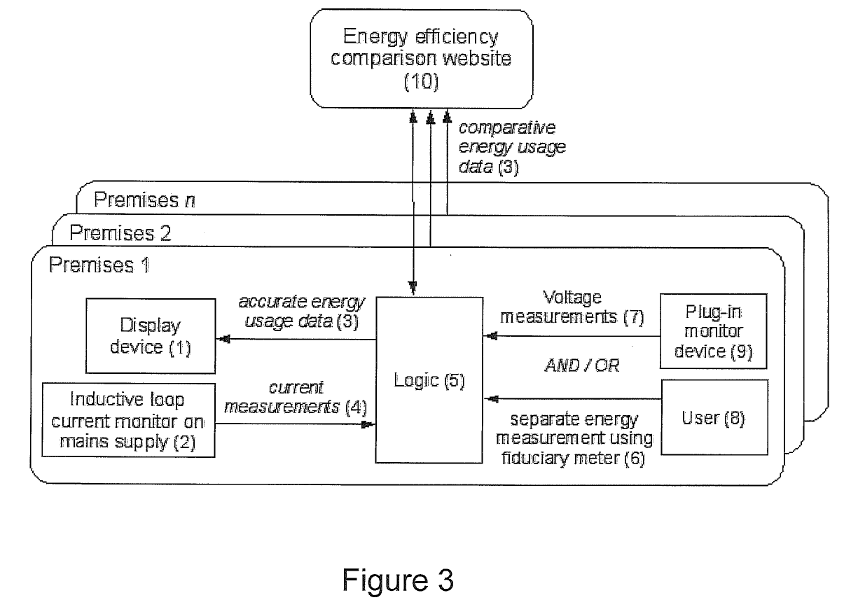

FIG. 3 illustrates in simplified form various parts of an embodiment of the invention, showing current flow data (4) being collected via a ‘clip-on’ meter (2), voltage data being collected by means of a plug-in monitor device (9) or manual meter readings by the user (8), and that data being shared with and compared to others via an energy efficiency web application (10).

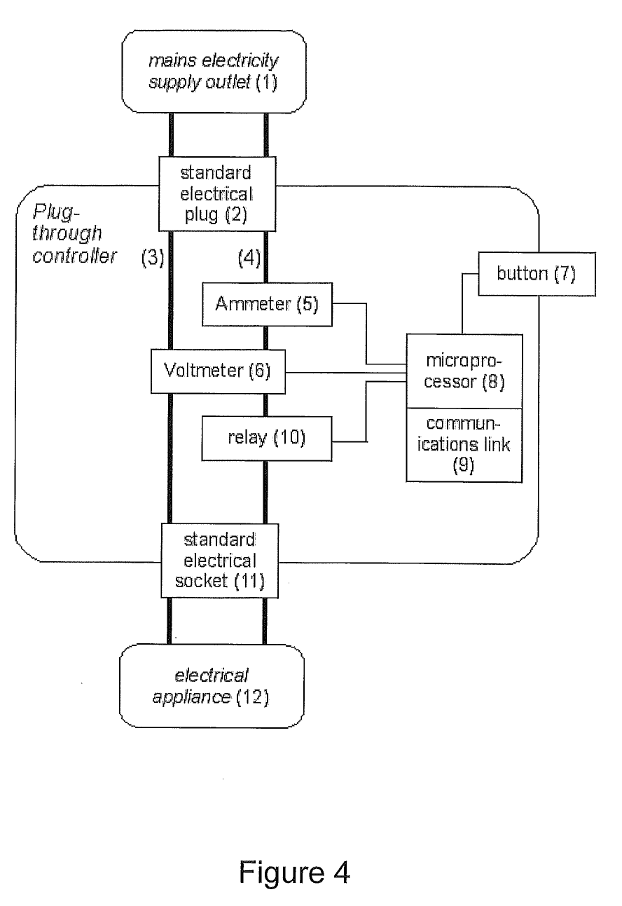

FIG. 4 shows a functional block diagram of an implementation of a plug-in mains voltage monitor as part of a plug-through controller. The controller connects to a standard mains electricity outlet (1) by means of a standard mains electricity plug (2), comprising at least two pins from which ‘live’ (4) and ‘neutral’ (3) conducting wires pass through the controller to a second standard mains electricity socket (11), in to which the controlled appliance (12) is plugged. An ammeter (5) placed in series on one or other of the conducting wires, and a Voltmeter (6) is connected across the them. Their measurements are reported to a microprocessor (8) running software which uses them to calculate the power being drawn by the appliance. The microprocessor may report the measurements by means of a communication link (9) to a separate processing unit, which has knowledge of the occupancy state of the controller's location and may respond by sending commands to turn the attached appliance on or off using a relay (10). The microprocessor also monitors a button (7) or similar human interface, and can switch on or off power to the controlled device according to its input

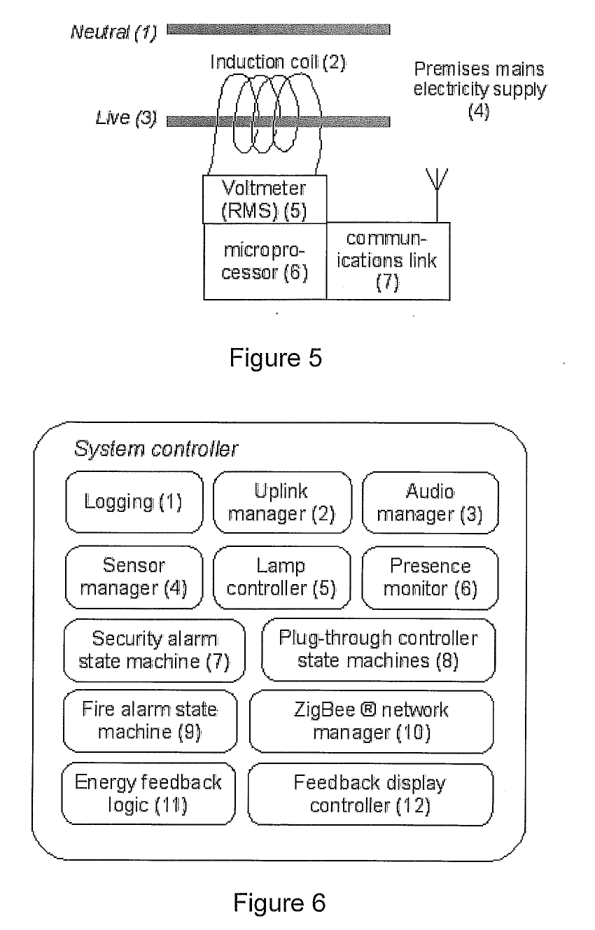

FIG. 5 shows the functional elements of an installed clip-on current meter. Most small-premises' fiduciary electricity meters require connection to the electrical mains (4) via ‘tails’ of mains cabling. At these tails the live (3) and neutral (1) mains lines are often accessible separately and the inductive loop (2) is better fitted around the live wire. The root-mean-square (RM) voltage on the coil is measured by a voltmeter (5) and converted by a microprocessor (6) to Amps of current flowing in the mains line, using a predetermined conversion factor dependant on the structure of the coil. A microprocessor (6) may further convert Amps per second to Watts of power. In any case, it wirelessly transmits (7) the data to a system controller or a display feedback device. In order to reduce the amount of radio traffic or reduce the latency in feedback updates, the reporting interval may be set long or short, or replaced by a rule requiring reports only when a change in electrical load is noted.

FIG. 6 shows schematically the functional elements of a combined home monitoring system controller. Logs (1) of data from sensors and local state are maintained and uploaded to the monitoring system remote monitoring centre periodically and on demand. An uplink manager (2) monitors the status of the internet connection and if necessary routes communications via GPRS cellular connection. An audio manager (3) prioritises and plays audio outputs and manages the library of audio files. A sensor manager module (4) maintains internal representations of the state of all the system's battery-powered sensors, including presence detectors, so that their state can be queried expeditiously while they are powered down in sleep cycles to conserve energy. A lamp controller (5) manages indicator lamps to show system state, information sent by the remote monitoring centre, or indicate present rate of electrical energy consumption. A presence monitor module maintains an internal representation of the location of plug-through controllers and presence detectors and the occupancy state thereof. A security alarm state machine (7) runs the security functions of the the system. Plug-through controller state machines (8) monitor and respond appropriately to the power and occupancy conditions obtaining at each plug-through controller. A fire alarm state machine (9) runs the fire safety function of the system. A ZigBee® network manager module (10) monitors and maintains the ZigBee® low-power radiocommunications network. Energy feedback logic (11) monitors energy measurements and energy performance relative to other premises and passes energy information for display to the feedback display controller (11) which communicates via ZigBee® with the feedback display itself

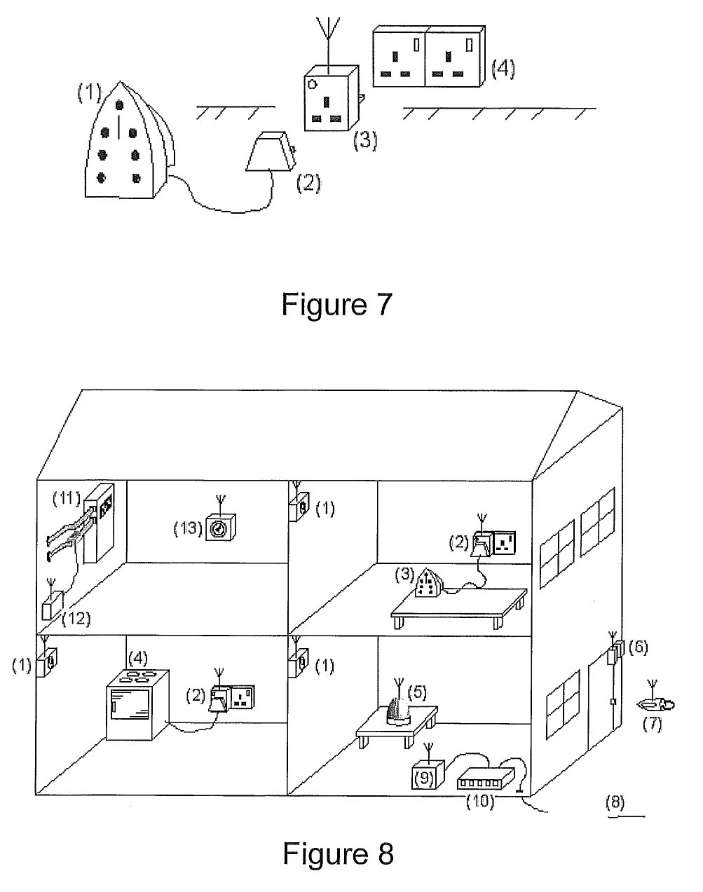

FIG. 7 shows an exploded diagram of a plug-in device suitable for monitoring of mains voltage and also monitoring and control of attached appliance. A plug-through controller (3) is interposed between a standard three-pin mains electricity socket (4) and an iron (1) or other electrical appliance. Mechanical and electrical coupling is by means of standard three-pin plugs (2) and sockets (4). Fulfilling dual functions of mains voltage monitor and monitor/controller of the attached appliance, the device should preferably ensure that its mains voltage measurements are taken while any attached appliance is turned off, in order to avoid possible under-reading of voltage de to resistive losses in the mains distribution network between the wall outlet and the fiduciary meter.

FIG. 8 shows this same arrangement (2) in use with an iron (3) and other electrical appliances, including an oven (4), in a domestic setting, as part of a domestic energy, occupancy and security monitoring system. Also depicted are PIR motion sensors (1) employed as presence detectors in each room, a magnetic contact sensor (6) used to detect opening of the front door, a keyfob (7) by operation of which users may arm or disarm the security system and whose presence in the building is taken to indicate the presence of its owner also, and an indicator lamp (5) placed in an easily observable position where it can be used to indicate present energy usage, using colours and blink patterns. A system controller (9) is connected by Ethernet to a network router/broadband modem (10), which provides a connection (8) to the internet and hence to the remote servers and monitoring centre. To the live tail of the fiduciary electricity mete (11) is attached an inductive coil current meter (12). Temperature sensors may be built in to each of these devices and the system can be enabled to manage heating efficiently, according to presence, time of day and ambient temperature, by the integration of a heating thermostat/controller (13).

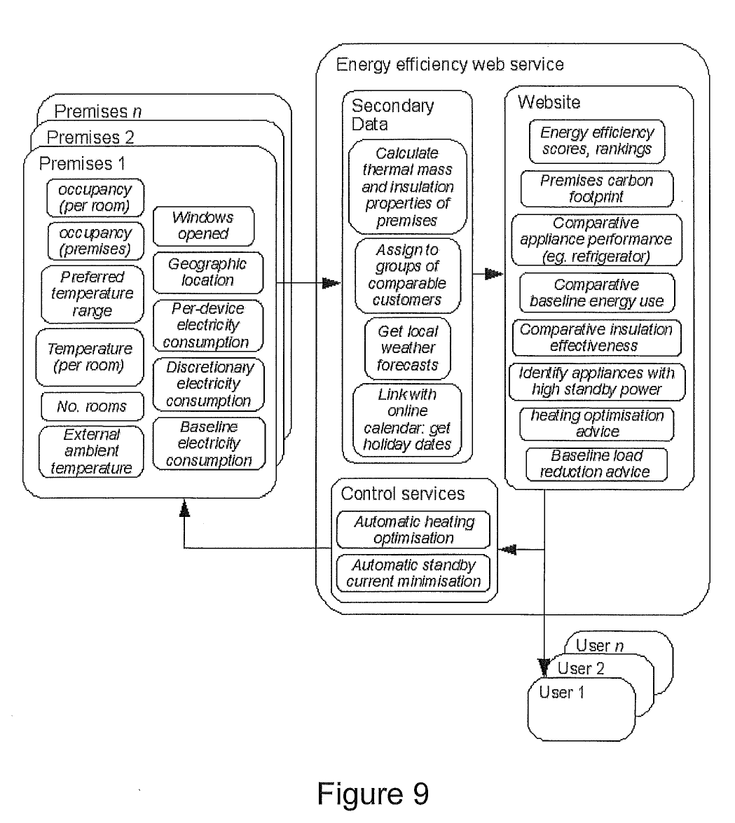

FIG. 9 shows in schematic form an example of information flow in an energy monitoring and comparative feedback service. Various pieces of information may be collected from a premises in addition to aggregate electrical energy consumption, and passed via the internet up to computer servers of an energy efficiency web service. These further augment the data with more premises-specific information obtained from other internet sites, and meta-information such as premises classification based on size, age, number of occupants etc. All these data are collected from multiple customers and their premises so that they can be compared and best practice and relative performance made clear, thus encouraging effective energy conservation. Part of the service may actively assist with energy conservation by engaging to automatically optimize heating programs and use of electricity by certain appliances.

The foregoing has been a detailed description of illustrative embodiments of the invention. Various modifications and additions can be made without departing from the spirit and scope of this invention. Each of the various embodiments described above may be combined with other described embodiments in order to provide multiple features. Furthermore, while the foregoing describes a number of separate embodiments of the apparatus and method of the present invention, what has been described herein is merely illustrative of the application of the principles of the present invention. Accordingly, this description is meant to be taken only by way of example, and not to otherwise limit the scope of this invention.

What is claimed is:

1. An electrical power supply consumption feedback system for providing feedback on power consumption in a building, the system comprising:
a current transducer configured to be attached externally to a mains power supply cable providing a mains power supply to said building to measure a current of said mains power supply;
a voltage measurement system configured to measure within said building a voltage of said mains power supply;
a system controller coupled to said voltage measurement system and to said current transducer and having a system controller wireless interface, at least one of said current transducer and said voltage measurement system having a complementary wireless interface and being coupled to said system controller via said system controller wireless interface, and wherein said system controller is configured to calculate a power consumption of said building from said measured current and voltage; and
a display coupled to said system controller to display a visual indication of said calculated power consumption.

2. An electrical power supply consumption feedback system as claimed in claim 1 further comprising one or more plug-through controllers each for one or both of monitoring and control of power consumption of an appliance connected to said mains power supply through the plug-through controller, and wherein said voltage measurement system comprises a said plug-through controller configured to measure a voltage of said mains power supply.

3. An electrical power supply consumption feedback system as claimed in claim 2 wherein a said plug-through controller is configured to selectively measure said voltage of said mains power supply when an appliance connected to the plug-through controller is switched off.

4. An electrical power supply consumption feedback system as claimed in claim 1 wherein said voltage measurement system comprises a user interface to enable a user to input two utility meter readings of said mains power supply to said building spaced apart by a time interval, said two utility meter readings representing an energy consumption of said building during said time interval, wherein said voltage measurement system is configured to determine an assumed voltage of said mains power supply from said two meter readings and measurements of said current over said time interval, and wherein said system controller is configured to use said assumed voltage to calculate said power consumption.

5. An electrical power supply consumption feedback system as claimed in claim 4 wherein said time interval is at least a day.

6. An electrical power supply consumption feedback system as claimed in claim 4 wherein said time interval is at least a week.

7. An electrical power supply consumption feedback system as claimed in claim 1 wherein said voltage measurement system comprises a system to remotely read a utility meter monitoring said mains power supply.

8. An electrical power supply consumption feedback system for providing feedback on power consumption in a building, the system comprising:
a plurality of in-building electrical power supply consumption monitoring systems, each having an interface for coupling the respective system to a network;
a system controller having an interface to said network for connecting to each of said monitoring systems to receive power consumption data from said monitoring systems; and
a plurality of user feedback terminals each for providing feedback on to a respective user of a monitored building and each couplable to said system controller to provide said feedback on in-building monitored power consumption; and
wherein said system controller is configured to provide to a user of said system, via a said user feedback terminal information on a relative power consumption of a monitored building of the user in comparison with one or more others of said monitored buildings.

9. A system as claimed in claim 8 further comprising an interface for a said user to input from said user energy efficiency data relating to an energy efficiency of a building, and wherein said relative power consumption is determined by selectively grouping said buildings dependent on said energy efficiency data and/or is adjusted using said energy efficiency data.

10. A system as claimed in claim 8 wherein a said in-building electrical power supply consumption monitoring system includes one or more of an occupancy detection system for the building or for one or more rooms of the building, and a temperature sensing system for the building or for one or more rooms of the building, and wherein said system controller is configured to provide to a user of said system information relating to a carbon footprint of a building.

11. A system as claimed in claim 9 wherein said system controller further comprises a module for estimating a heat input to a said building, and wherein a said user feedback terminal is configured to display, dependent on said estimated heat input, information dependent on an overall energy efficiency of said building.

12. A system as claimed in claim 8 wherein a said in-building electrical power supply consumption monitoring system comprises an electrical power supply consumption feedback system as claimed in claim 1.
